(19) United States
(12) Patent Application Publication
(10) Pub. No.: US 2026/0164809 A1
(43) Pub. Date: Jun. 11, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Donghe Du, Singapore (SG); Xiao Zhong Zhu, Singapore (SG)

(73) Assignee: UNITED MICROELECTRONICS CORP., Hsin-Chu City (TW)

(21) Appl. No.: 19/007,536

(22) Filed: Jan. 1, 2025

(30) Foreign Application Priority Data
Dec. 11, 2024 (TW) 113147999

(51) Int. Cl. H10D 89/60; H10D 30/01; H10D 30/65; H10D 62/10; H10D 64/23; H10D 64/66

(52) U.S. Cl. CPC H10D 89/811; H10D 30/0285; H10D 30/65; H10D 62/124; H10D 64/256; H10D 64/663; H10D 64/675

(57) ABSTRACT

A semiconductor structure includes a semiconductor substrate; a source structure in the semiconductor substrate, wherein the source structure includes a source drift region and a heavily doped source region within the source drift region; a recessed trench disposed in the semiconductor substrate and spaced apart from the source structure; a drain structure disposed at a bottom of the recessed trench, wherein the drain structure includes a drain drift region, a heavily doped drain region disposed within the drain drift region, and a carbon-doped surface layer on the heavily doped drain region; and a gate structure disposed on the semiconductor substrate between the source structure and the drain structure.

### BACKGROUND OF THE INVENTION

### 1. Field of the Invention

The present invention relates to the field of semiconductor technology, and in particular to an electrostatic discharge (ESD) protection device and a manufacturing method thereof.

### 2. Description of the Prior Art

An electrostatic discharge (ESD) device is used to protect internal circuitry on a semiconductor chip. The ESD devices are connected to each chip input/output (I/O) and power pad. When an electrostatic discharge external to the chip enters a chip pad, the ESD devices and circuits absorb the resulting high current and protect the internal chip circuitry form damage. The ESD devices are usually located near the chip pad to which they are connected.

It has been found that the ESD devices may suffer from CoSi spiking, a phenomenon where CoSi spikes form and grow during electrical stress. The formation of CoSi spikes creates localized conductive paths, leading to increased leakage current in the device. This can degrade the device's performance and reduce its reliability. CoSi spikes can act as stress concentrators, weakening the dielectric material and lowering the breakdown voltage of the ESD device. This makes the device more susceptible to damage from ESD events.

### SUMMARY OF THE INVENTION

It is one object of the present invention to provide an improved semiconductor ESD device structure and its manufacturing method to solve the deficiencies or shortcomings of the existing technology.

One aspect of the invention provides a semiconductor structure including a semiconductor substrate having a first conductivity type; a source structure disposed in the semiconductor substrate, a recessed trench disposed in the semiconductor substrate and being spaced apart from the source structure; and a drain structure disposed at a bottom of the recessed trench. The source structure includes a source drift region having a second conductivity type and a heavily doped source region having the second conductivity type disposed within the source drift region. The drain structure includes a drain drift region of the second conductivity type, a heavily doped drain region having the second conductivity type disposed within the drain drift region, and a carbon-doped surface layer on the heavily doped drain region. A gate structure is disposed on the semiconductor substrate between the source structure and the drain structure.

According to some embodiments, the gate structure comprises a gate electrode, a first spacer on a first sidewall of the gate electrode, a second spacer on a second sidewall of the gate electrode, and a gate dielectric layer between the gate electrode and the semiconductor substrate.

According to some embodiments, the source drift region completely overlaps with the first spacer and partially overlaps with the gate electrode when viewed from above.

According to some embodiments, the drain drift region does not overlap with the second spacer and the gate electrode when viewed from above.

According to some embodiments, the recessed trench comprises a sidewall disposed adjacent to an outer surface of the first spacer.

According to some embodiments, a rounded corner is disposed between the sidewall of the recessed trench and the bottom of the recessed trench.

According to some embodiments, the recessed trench has a depth ranging between 1000 and 2500 angstroms below a main surface of the semiconductor substrate.

According to some embodiments, the semiconductor structure further includes a first silicide layer disposed on the heavily doped source region; a second silicide layer disposed on the heavily doped drain region, wherein an end of the second silicide layer is kept a predetermined distance from the sidewall of the recessed trench; and a third silicide layer disposed on a top portion of the gate electrode adjacent to the source structure.

According to some embodiments, the first silicide layer, the second silicide layer, and the third silicide layer comprise cobalt silicide.

According to some embodiments, the first conductivity type is P type and the second conductivity type is N type.

Another aspect of the invention provides a method for forming a semiconductor structure. A semiconductor substrate having a first conductivity type is provided. A source structure is formed in the semiconductor substrate. The source structure comprises a source drift region having a second conductivity type and a heavily doped source region having the second conductivity type disposed within the source drift region. A recessed trench is formed in the semiconductor substrate, wherein the recessed trench is spaced apart from the source structure. A drain structure is formed at a bottom of the recessed trench. The drain structure includes a drain drift region of the second conductivity type, a heavily doped drain region having the second conductivity type disposed within the drain drift region, and a carbon-doped surface layer on the heavily doped drain region. A gate structure is formed on the semiconductor substrate between the source structure and the drain structure.

According to some embodiments, the gate structure comprises a gate electrode, a first spacer on a first sidewall of the gate electrode, a second spacer on a second sidewall of the gate electrode, and a gate dielectric layer between the gate electrode and the semiconductor substrate.

According to some embodiments, the source drift region completely overlaps with the first spacer and partially overlaps with the gate electrode when viewed from above.

According to some embodiments, the drain drift region does not overlap with the second spacer and the gate electrode when viewed from above.

According to some embodiments, the recessed trench comprises a sidewall disposed adjacent to an outer surface of the first spacer.

According to some embodiments, a rounded corner is disposed between the sidewall of the recessed trench and the bottom of the recessed trench.

According to some embodiments, the recessed trench has a depth ranging between 1000 and 2500 angstroms below a main surface of the semiconductor substrate.

According to some embodiments, the method further includes the steps of forming a first silicide layer on the heavily doped source region; forming a second silicide layer on the heavily doped drain region, wherein an end of the second silicide layer is kept a predetermined distance from the sidewall of the recessed trench; and forming a third silicide layer on a top portion of the gate electrode adjacent to the source structure.

According to some embodiments, the first silicide layer, the second silicide layer, and the third silicide layer comprise cobalt silicide.

According to some embodiments, the first conductivity type is P type and the second conductivity type is N type.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial layout diagram illustrating a semiconductor structure according to an embodiment of the present invention.

FIG. 2 to FIG. 8 are schematic cross-sectional views taken along line I-I′ in FIG. 1, illustrating a method for manufacturing a semiconductor structure.

FIG. 9 is a cross-sectional view illustrating a partial semiconductor structure of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

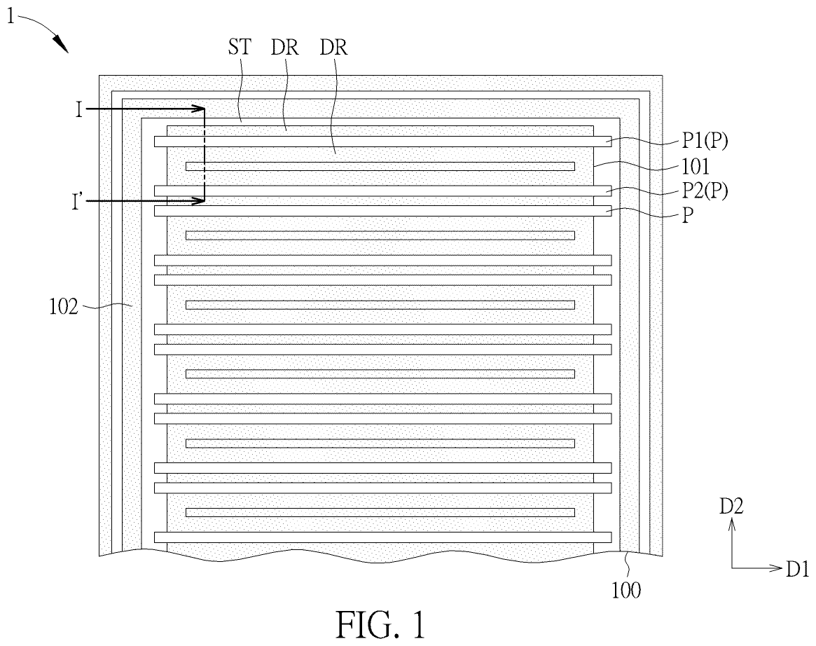

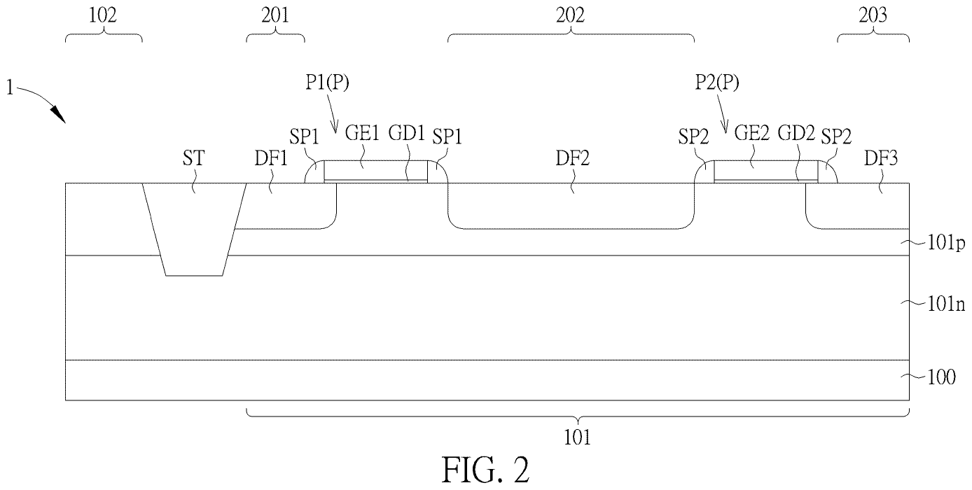

Please refer to FIG. 1 to FIG. 8, wherein FIG. 1 is a partial layout diagram of a semiconductor structure according to an embodiment of the present invention, and FIG. 2 to FIG. 8 are cross-sectional schematic diagrams taken along line I-I′ in FIG. 1, which illustrate a method of manufacturing a semiconductor structure.

As shown in FIG. 1, the semiconductor structure 1 of the present invention can be used in applications including, but not limited to, electrostatic discharge (ESD) protection devices, which are fabricated on a semiconductor substrate 100, where the semiconductor substrate 100 may be, for example, a silicon substrate or any suitable semiconductor substrates. It should be understood that FIG. 1 only shows a partial enlarged view of the ESD protection device as an example for the sake of simplicity. According to an embodiment of the present invention, the semiconductor structure 1 includes an active region 101, a trench isolation region ST surrounding the active region 101, a plurality of gate structures P extending along a first direction D1, and doped regions DR located on both sides of the gate structure P. The doped region DR may be, for example, an N+ doped region, serving as the drain or source of the ESD protection device

According to an embodiment of the present invention, the semiconductor substrate 100 may have a first conductivity type, for example, P type, but is not limited thereto. According to an embodiment of the present invention, the plurality of gate structures P are arranged parallel to each other with a predetermined spacing in the second direction D2. According to an embodiment of the present invention, the semiconductor structure 1 may further include an annular heavily doped region 102 located on the periphery of the trench isolation region ST, for example, a P+ doped region, but is not limited thereto.

As shown in FIG. 2, an input/output P-well (I/O P well) 101p may be formed in the semiconductor substrate 100. Under the I/O P-well 101p, a deep N-well 101n may be formed. Adjacent gate structures P1 and P2 are formed on the semiconductor substrate 100. For example, the gate structure P1 includes a gate electrode GE1, a gate dielectric layer GD1 located between the gate electrode GE1 and the semiconductor substrate 100, and spacers SP1 located on opposite sidewalls of the gate electrode GE1. Similarly, the gate structure P2 includes a gate electrode GE2, a gate dielectric layer GD2 located between the gate electrode GE2 and the semiconductor substrate 100, and spacers SP2 located on opposite sidewalls of the gate electrode GE2.

According to an embodiment of the present invention, for example, the gate electrodes GE1 and GE2 may comprise polysilicon, but are not limited thereto. According to an embodiment of the present invention, for example, the gate dielectric layers GD1 and GD2 may comprise silicon oxide, but are not limited thereto. According to an embodiment of the present invention, for example, the spacers SP1 and SP2 may comprise silicon nitride, silicon oxide, or silicon oxynitride, but are not limited thereto.

According to an embodiment of the present invention, a drain region 202 is located between the gate electrodes GE1 and GE2, a source region 201 is located on the other side of the gate electrode GE1 opposite to the drain region 202, and another source region 203 is located on the other side of the gate electrode GE2 opposite to the drain region 202. According to an embodiment of the present invention, the width of the drain region 202 may be larger than the widths of the source regions 201 and 203.

According to an embodiment of the present invention, a source drift region DF1 having a second conductivity type is formed in the source region 201, a drain drift region DF2 having the second conductivity type is formed in the drain region 202, and a source drift region DF3 having the second conductivity type is formed in the source region 203, wherein the drain drift region DF2, the source drift region DF1, and the source drift region DF3 are, for example, N-type drift regions.

According to an embodiment of the present invention, when viewed from above, the source drift region DF1 completely overlaps the spacer SP1 and partially overlaps the gate electrode GE1, and the source drift region DF2 completely overlaps the spacer SP2 and partially overlaps the gate electrode GE2. According to an embodiment of the present invention, when viewed from above, the drain drift region DF2 does not overlap the spacers SP1 and SP2 or the gate electrodes GE1 and GE2.

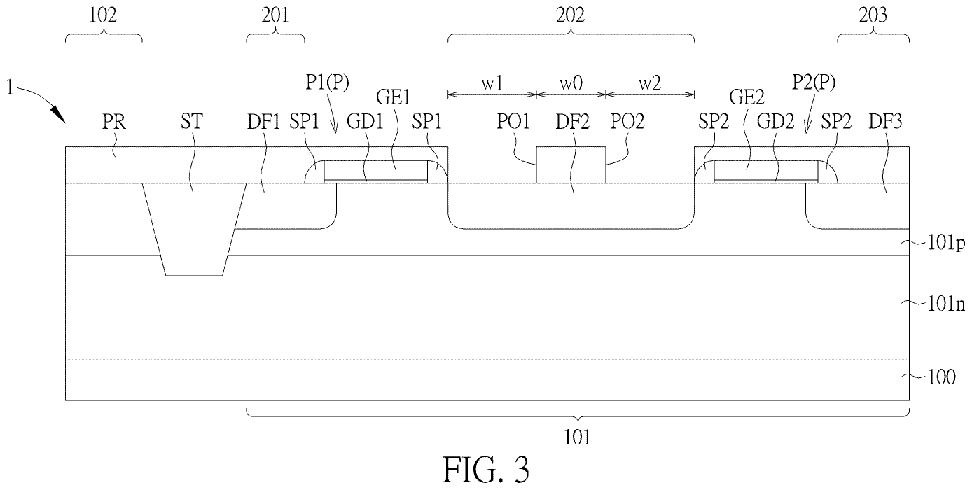

As shown in FIG. 3, a photoresist pattern PR is formed on the semiconductor substrate 100. The photoresist pattern PR has an opening PO1 with a width of w1 and an opening P02 with a width of w2, respectively exposing a portion of the drain region 202 adjacent to the gate structure P1 and a portion of the drain region 202 adjacent to the gate structure P2. According to an embodiment of the present invention, a predetermined distance w0 is maintained between the openings PO1 and P02. According to an embodiment of the present invention, the sum of the widths w1, w2, and the predetermined distance w0 is approximately equal to the width of the drain region 202. According to an embodiment of the present invention, the opening PO1 may expose a portion of the spacer SP1, while the opening P02 may expose a portion of the spacer SP2.

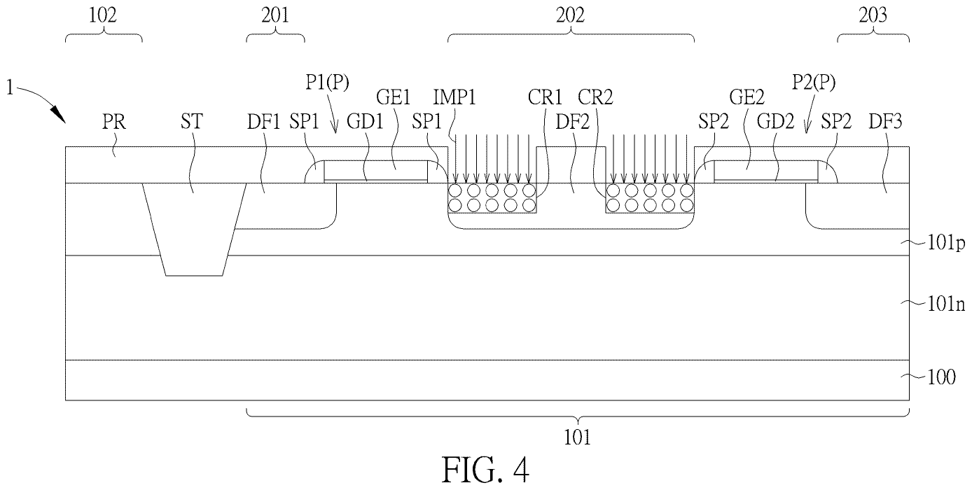

As shown in FIG. 4, a carbon ion implantation process IMP1 is then performed. Through the openings PO1 and P02 of the photoresist pattern PR, carbon atoms are implanted into the P well 101p in the drain region 202, forming a carbon-doped region CR1 and a carbon-doped region CR2. According to an embodiment of the present invention, for example, the implantation dose of the carbon ion implantation process IMP1 is about 1E14/cm², and the implantation depth is about 1200 to 2700 angstroms, but is not limited thereto. The carbon-doped regions CR1 and CR2 can prevent the formation of CoSi spikes and dopant diffusion.

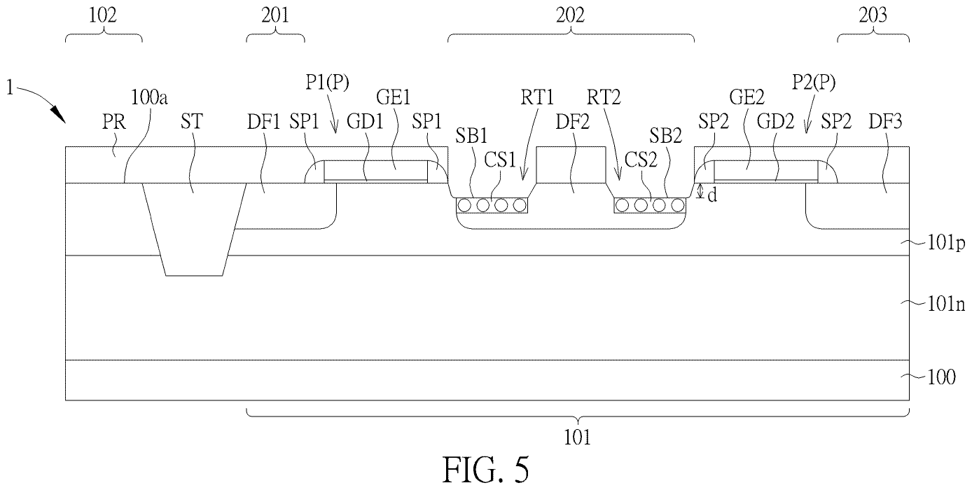

As shown in FIG. 5, an etching process, such as an anisotropic dry etching process, is then performed. Using the photoresist pattern PR in FIG. 4 as an etching mask, through the openings PO1 and P02, respectively, a recessed trench RT1 and a recessed trench RT2 are formed in the P well 101p. According to an embodiment of the present invention, for example, the depth d of the recessed trenches RT1 and RT2 below the main surface 100a of the semiconductor substrate 100 may be between 1000 and 2500 angstroms. According to an embodiment of the present invention, the depth d of the recessed trenches RT1 and RT2 is less than the implantation depth of the carbon-doped regions CR1 and CR2. According to an embodiment of the present invention, at this point, carbon-doped surface layers CS1 and CS2 are still retained at the bottoms SB1 and SB2 of the recessed trenches RT1 and RT2, respectively.

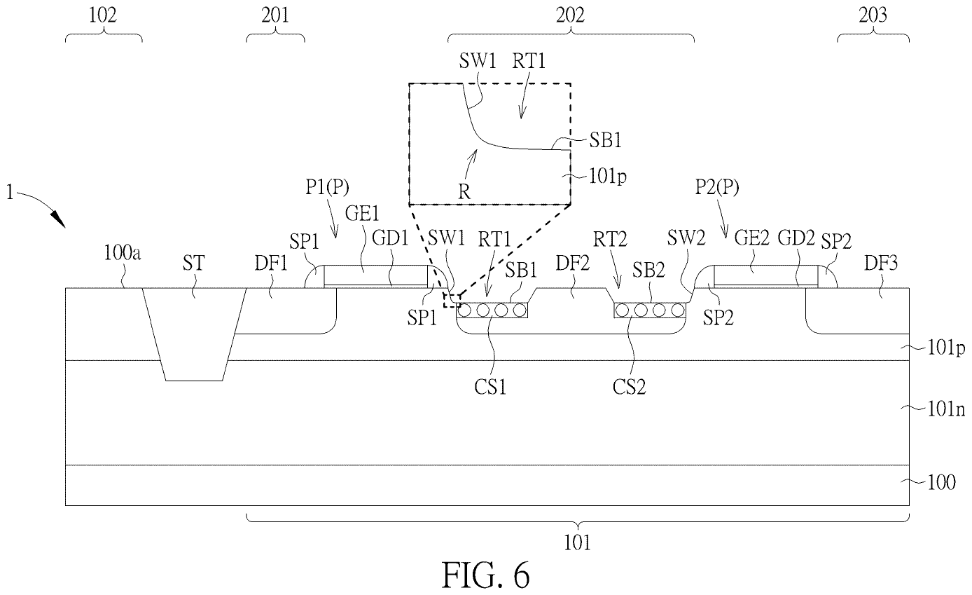

As shown in FIG. 6, the photoresist pattern PR is removed through a photoresist stripping process followed by a cleaning process. According to an embodiment of the present invention, the aforementioned cleaning process can utilize a diluted hydrofluoric acid solution and an SPM solution. For example, the SPM solution can be a mixture of sulfuric acid solution and hydrogen peroxide aqueous solution at a ratio of 3:1. According to an embodiment of the present invention, after the aforementioned cleaning process, the corners R between the sidewalls SW1 and SW2 and the bottoms SB1 and SB2 of the recessed trenches RT1 and RT2, respectively, are rounded, as shown in the partial enlarged view. This serves to reduce the peak electric field strength and prevent the formation of CoSi spikes.

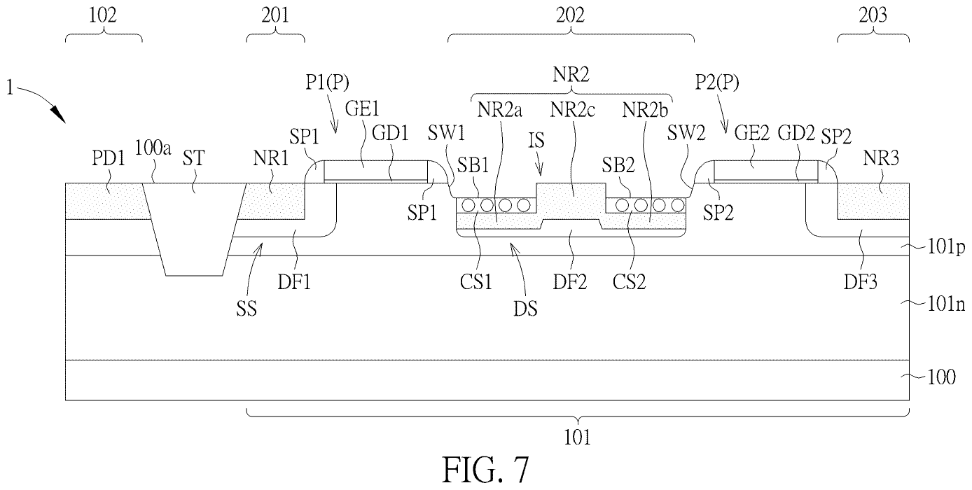

As shown in FIG. 7, an ion implantation process is then performed to form a P+ doped region PD1 in the annular heavily doped region 102, and heavily doped source regions NR1 and NR3 are formed in the source drift regions DF1 and DF3, respectively, while a heavily doped drain region NR2 is formed in the drain drift region DF2. According to an embodiment of the present invention, the heavily doped source regions NR1 and NR3 and the heavily doped drain region NR2 are, for example, N+ doped regions. According to an embodiment of the present invention, the heavily doped drain region NR2 includes a heavily doped drain region NR2a located at the bottom SB1 of the recessed trench RT1, a heavily doped drain region NR2b located at the bottom SB2 of the recessed trench RT2, and a heavily doped drain region NR2c in the island region IS located between the recessed trenches RT1 and RT2.

According to an embodiment of the present invention, the heavily doped drain region NR2a located at the bottom SB1 of the recessed trench RT1 and the heavily doped drain region NR2b located at the bottom SB2 of the recessed trench RT2 have substantially the same junction depth, while the junction depth of the heavily doped drain region NR2c can be smaller than the junction depth of the heavily doped drain regions NR2a and NR2b. Subsequently, a rapid thermal processing (RTP) process can be performed to activate the dopants implanted in the semiconductor substrate 100. At this point, a source structure SS is formed in the semiconductor substrate 100, and a drain structure DS is formed at the bottoms of the recessed trenches RT1 and RT2.

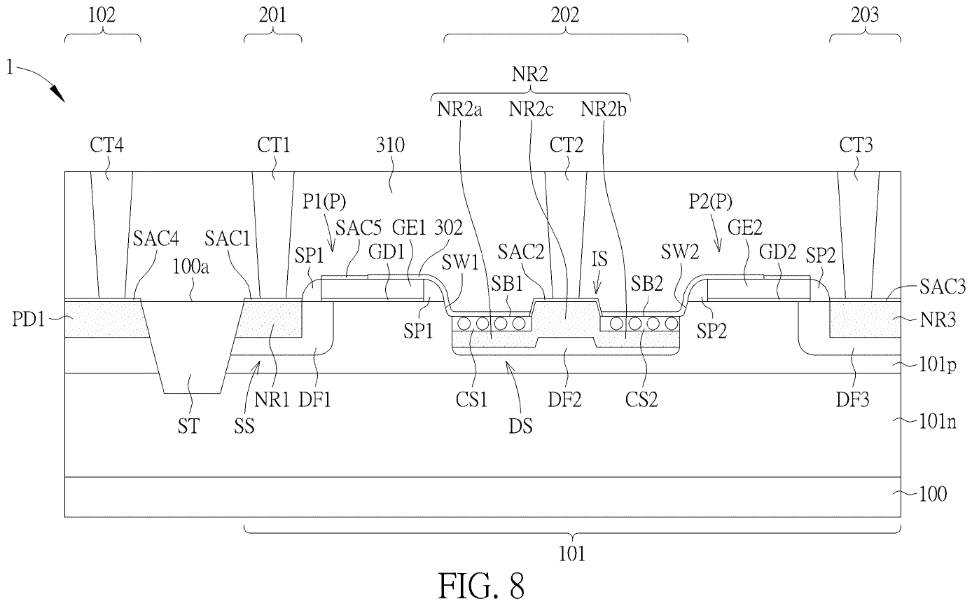

As shown in FIG. 8, a salicide block layer 302 is then formed on the semiconductor substrate 100, covering the portion of the top surface of the gate electrodes GE1 and GE2 close to the drain structure DS, the outer surfaces of the spacers SP1 and SP2 close to the drain structure DS, the sidewalls SW1 and SW2 of the recessed trenches RT1 and RT2, and the top surfaces of the heavily doped drain regions NR2a and NR2b.

Next, a self-aligned silicide process is performed to form silicide layers SAC1-SAC5, for example, cobalt silicide (CoSi), on the surface of the semiconductor substrate 100 that is not covered by the silicide blocking layer 302. The silicide layers SAC1 and SAC3 are formed on the surfaces of the heavily doped source regions NR1 and NR3, respectively. The silicide layer SAC2 is formed on the surface of the heavily doped drain region NR2c in the island region IS between the recessed trenches RT1 and RT2. The silicide layer SAC4 is formed on the surface of the P+ doped region PD1 within the annular heavily doped region 102. The silicide layer SAC5 is formed on the top of the gate electrodes GE1 and GE2 near the source structure SS. According to an embodiment of the present invention, the end of the silicide layer SAC2 is kept a predetermined distance from the sidewalls SW1 and SW2 of the trenches RT1 and RT2.

Subsequently, a chemical vapor deposition (CVD) process is performed to deposit a dielectric layer 310 on the entire surface of the semiconductor substrate 100. The dielectric layer 310 may be a silicon oxide layer, but not limited thereto. A metallization process is then performed to form contact plugs CT1-CT4 in the dielectric layer 310. The contact plugs CT1 and CT3 contact the silicide layers SAC1 and SAC3 on the heavily doped source regions NR1 and NR3, respectively. The contact plug CT2 contacts the silicide layer SAC2 on the heavily doped drain region NR2c. The contact plug CT3 contacts the silicide layer SAC4 on the P+ doped region PD1.

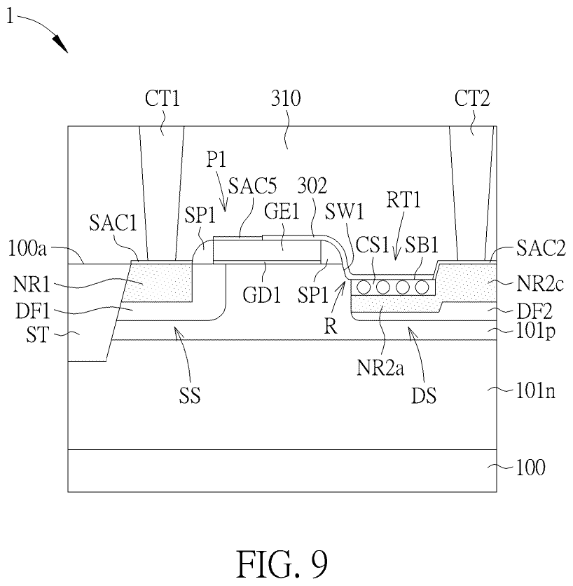

Please refer to FIG. 9, which is a cross-sectional view of a partial semiconductor structure drawn according to an embodiment of the present invention. In the figures, the same regions, materials, or layers are represented by the same reference numerals. As shown in FIG. 9, the semiconductor structure 1 includes a semiconductor substrate 100 having a first conductivity type, for example, P-type. An input/output P-type well (I/O P well) 101p can be formed in the semiconductor substrate 100, and a deep N-type well 101n can be further formed below the I/O P well 101p. A source structure SS and a drain structure DS are provided in the semiconductor substrate 100. The source structure SS is spaced apart from the drain structure DS. According to an embodiment of the present invention, the source structure SS includes a source drift region DF1 and a heavily doped source region NR1 provided in the source drift region DF1. The source drift region DF1 and the heavily doped source region NR1 have a second conductivity type, for example, N-type.

According to an embodiment of the present invention, a recessed trench RT1 is provided in the semiconductor substrate 100, and the recessed trench RT1 is spaced apart from the source structure SS. According to an embodiment of the present invention, a portion of the drain structure DS is provided at the bottom of the recessed trench RT1, wherein the drain structure DS includes a drain drift region DF2, a heavily doped drain region NR2a provided in the drain drift region DF2, and a carbon-doped surface layer CS1 located on the heavily doped drain region NR2a.

According to an embodiment of the present invention, a gate structure P1 is provided on the semiconductor substrate 100, wherein the gate structure P1 is located between the source structure SS and the drain structure DS.

According to an embodiment of the present invention, the gate structure P1 includes a gate electrode GE1, spacers SP1 on the opposite sidewalls of the gate electrode GE1, and a gate dielectric layer GD1 between the gate electrode GE1 and the semiconductor substrate 100.

According to an embodiment of the present invention, when viewed from above, the source drift region DF1 completely overlaps the spacer SP1 on the source side and partially overlaps the gate electrode GE1. According to an embodiment of the present invention, when viewed from above, the drain drift region DF2 does not overlap the spacer SP1 or the gate electrode GE1 on the drain side.

According to an embodiment of the present invention, a recessed trench RT1 includes a sidewall SW1 provided adjacent to the outer surface of the spacer SP1. According to an embodiment of the present invention, the corner R between the sidewall SW1 of the recessed trench RT1 and the bottom of the recessed trench RT1 is a rounded corner. According to an embodiment of the present invention, the depth of the recessed trench RT1 below the main surface 100a of the semiconductor substrate 100 is between 1000 angstroms and 2500 angstroms.

According to an embodiment of the present invention, the semiconductor structure 1 further includes a silicide layer SAC1 provided on the heavily doped source region NR1, a silicide layer SAC2 provided on the heavily doped drain region NR2c, wherein the end of the silicide layer SAC2 maintains a predetermined distance from the sidewall SW1 of the recessed trench RT1. The semiconductor structure 1 further includes a silicide layer SAC5 provided on the top of the gate electrode GE1 and near the source structure SS. According to an embodiment of the present invention, for example, the silicide layers SAC1, SAC2, and SAC5 include cobalt silicide.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a semiconductor substrate having a first conductivity type;
a source structure disposed in the semiconductor substrate, wherein the source structure comprises a source drift region having a second conductivity type and a heavily doped source region having the second conductivity type disposed within the source drift region;
a recessed trench disposed in the semiconductor substrate and being spaced apart from the source structure;
a drain structure disposed at a bottom of the recessed trench, wherein the drain structure comprises a drain drift region of the second conductivity type, a heavily doped drain region having the second conductivity type disposed within the drain drift region, and a carbon-doped surface layer on the heavily doped drain region; and
a gate structure disposed on the semiconductor substrate between the source structure and the drain structure.

2. The semiconductor structure according to claim 1, wherein the gate structure comprises a gate electrode, a first spacer on a first sidewall of the gate electrode, a second spacer on a second sidewall of the gate electrode, and a gate dielectric layer between the gate electrode and the semiconductor substrate.

3. The semiconductor structure according to claim 2, wherein the source drift region completely overlaps with the first spacer and partially overlaps with the gate electrode when viewed from above.

4. The semiconductor structure according to claim 2, wherein the drain drift region does not overlap with the second spacer and the gate electrode when viewed from above.

5. The semiconductor structure according to claim 2, wherein the recessed trench comprises a sidewall disposed adjacent to an outer surface of the first spacer.

6. The semiconductor structure according to claim 5, wherein a rounded corner is disposed between the sidewall of the recessed trench and the bottom of the recessed trench.

7. The semiconductor structure according to claim 1, wherein the recessed trench has a depth ranging between 1000 and 2500 angstroms below a main surface of the semiconductor substrate.

8. The semiconductor structure according to claim 5 further comprising:
a first silicide layer disposed on the heavily doped source region;
a second silicide layer disposed on the heavily doped drain region, wherein an end of the second silicide layer is kept a predetermined distance from the sidewall of the recessed trench; and
a third silicide layer disposed on a top portion of the gate electrode adjacent to the source structure.

9. The semiconductor structure according to claim 8, wherein the first silicide layer, the second silicide layer, and the third silicide layer comprise cobalt silicide.

10. The semiconductor structure according to claim 1, wherein the first conductivity type is P type and the second conductivity type is N type.

11. A method for forming a semiconductor structure, comprising:
providing a semiconductor substrate having a first conductivity type;
forming a source structure in the semiconductor substrate, wherein the source structure comprises a source drift region having a second conductivity type and a heavily doped source region having the second conductivity type disposed within the source drift region;
forming a recessed trench in the semiconductor substrate, wherein the recessed trench is spaced apart from the source structure;
forming a drain structure at a bottom of the recessed trench, wherein the drain structure comprises a drain drift region of the second conductivity type, a heavily doped drain region having the second conductivity type disposed within the drain drift region, and a carbon-doped surface layer on the heavily doped drain region; and
forming a gate structure on the semiconductor substrate between the source structure and the drain structure.

12. The method according to claim 11, wherein the gate structure comprises a gate electrode, a first spacer on a first sidewall of the gate electrode, a second spacer on a second sidewall of the gate electrode, and a gate dielectric layer between the gate electrode and the semiconductor substrate.

13. The method according to claim 12, wherein the source drift region completely overlaps with the first spacer and partially overlaps with the gate electrode when viewed from above.

14. The method according to claim 12, wherein the drain drift region does not overlap with the second spacer and the gate electrode when viewed from above.

15. The method according to claim 12, wherein the recessed trench comprises a sidewall disposed adjacent to an outer surface of the first spacer.

16. The method according to claim 15, wherein a rounded corner is disposed between the sidewall of the recessed trench and the bottom of the recessed trench.

17. The method according to claim 11, wherein the recessed trench has a depth ranging between 1000 and 2500 angstroms below a main surface of the semiconductor substrate.

18. The method according to claim 15 further comprising:
forming a first silicide layer on the heavily doped source region;
forming a second silicide layer on the heavily doped drain region, wherein an end of the second silicide layer is kept a predetermined distance from the sidewall of the recessed trench; and
forming a third silicide layer on a top portion of the gate electrode adjacent to the source structure.

19. The method according to claim 18, wherein the first silicide layer, the second silicide layer, and the third silicide layer comprise cobalt silicide.

20. The method according to claim 11, wherein the first conductivity type is P type and the second conductivity type is N type.
